(19) United States
(12) Patent Application Publication
(10) Pub. No.: US 2021/0203375 A1
(43) Pub. Date: Jul. 1, 2021

(54) SWITCH CONTROL CIRCUIT, CARRIER AGGREGATION METHOD AND DEVICE, AND COMMUNICATION APPARATUS

(71) Applicant: ZTE CORPORATION, Shenzhen (CN)

(72) Inventor: Kai WANG, Shenzhen (CN)

(73) Assignee: ZTE CORPORATION

(21) Appl. No.: 17/200,826

(22) Filed: Mar. 13, 2021

Related U.S. Application Data
(63) Continuation of application No. PCT/CN2019/101336, filed on Aug. 19, 2019.

(30) Foreign Application Priority Data
Sep. 13, 2018 (CN) 201811070149.1

(51) Int. Cl. H04B 1/44; H04B 1/00; H04B 1/401; H04L 5/00; H03K 17/51

(52) U.S. Cl. CPC H04B 1/44; H04B 1/0064; H03K 17/51; H04L 5/001; H04B 1/401

(57) ABSTRACT

The application discloses a switch control circuit, a carrier aggregation method and device, and a communication apparatus. The switch control circuit comprises at least one composite switch, wherein: the composite switch comprises a plurality of switch units, each switch unit of the plurality of switch units has a first terminal, a second terminal and a third terminal, the first terminal is provided with a throw knife that is capable of being connected to the second terminal, and the third terminal is provided with a throw knife that is capable of being connected to the second terminal.

### CROSS-REFERENCES TO RELATED APPLICATIONS

This application is a continuation of PCT Application No. PCT/CN2019/101336, filed Aug. 19, 2019, entitled “Switch Control Circuit, Carrier Aggregation Method and Device, and Communication Apparatus”, which claims priority to Chinese Patent Application No. 201811070149.1, entitled “Switch Control Circuit, Carrier Aggregation Method and Device, and Communication Apparatus,” filed Sep. 13, 2018, each of which is hereby incorporated by reference in its entirety.

### TECHNICAL FIELD

This application relates to wireless communication technology, and in particular to a switch control circuit, a carrier aggregation method and device, and a communication apparatus.

### BACKGROUND

Carrier Aggregation (CA) is widely used in 4G (4^{th} Generation) terminals. As the operators' demand is increasing, the number of CA band combinations that need to be supported and are compatible with terminals is increasing when designing the terminal. Higher challenges are proposed to insertion loss and power consumption of RF front-end circuits, even bring about a situation that some complex CA combination circuit schemes cannot meet index requirements. Especially for concurrent operation of multi-carrier in the future 5G (5^{th} Generation) communication, as 5G has high frequencies, wide bands and higher requirements for RF front-end combiners, if a carrier aggregation function for the bands of sub 6G or even 5G millimeter has to be achieved, the requirements for impedance characteristics of components on radio frequency links will become higher, which may bring difficulties to the implementation of CA.

### SUMMARY

In order to solve the above technical problems, embodiments of the present application provide a switch control circuit, a carrier aggregation method and device, and a communication apparatus.

The switch control circuit according to the embodiments of the present application comprises at least one composite switch, wherein, the composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal.

The carrier aggregation device according to the embodiments of the application comprises the above-mentioned switch control circuit, a first antenna and a second antenna, where, the switch control circuit is configured to control at least one first band to be connected to a first antenna, and control at least one second band to be connected to a second antenna; the first antenna is configured to transmit respective carrier signals in the at least one first band; the second antenna is configured to transmit respective carrier signals in the at least one second band.

The communication apparatus according to the embodiments of the present application comprises the above-mentioned carrier aggregation device, a band filter circuit, and a radio frequency transceiver chip; wherein, the radio frequency transceiver chip is configured to send to or receive from the band filter circuit, carrier signals in at least one band; the band filter circuit is configured to receive carrier signals in at least one band from the radio frequency transceiver chip, filter the carrier signals in at least one band, and send them to the carrier aggregation device; or, receive carrier signals in at least one band from the carrier aggregation device, filter the carrier signals in at least one band, and send them to the radio frequency transceiver chip; and the carrier aggregation device is configured to send to or receive from the band filter circuit, carrier signals in at least one band.

The carrier aggregation method according to the embodiments of the present application comprises: controlling, by a switch control circuit, at least one first band to be connected to a first antenna and controlling, by the switch control circuit, at least one second band to be connected to a second antenna, wherein, the switch control circuit comprises at least one composite switch, and the composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal; and transmitting, by the first antenna, respective carrier signals of at least one first band through the first antenna, and transmitting, by the second antenna, respective carrier signals in at least one second band.

### BRIEF DESCRIPTION OF THE DRAWINGS

FIG. 1 is a schematic diagram illustrating the concept of CA;

FIG. 2(a) is a first schematic diagram illustrating a circuit of a 2DLCA;

FIG. 2(b) is a second schematic diagram illustrating the circuit of the 2DLCA;

FIG. 2(c) is a schematic diagram illustrating a circuit of a 3DLCA;

FIG. 3 is a schematic diagram illustrating a structural composition of a switch control circuit according to an embodiment of the present application;

FIG. 4 is a schematic diagram illustrating a switch unit according to an embodiment of the present application;

FIG. 5 is a schematic diagram illustrating a multi-path composite switch composed of basic switch units according to an embodiment of the present application;

FIG. 6 is an exploded schematic diagram illustrating a multi-path composite switch according to an embodiment of the present application;

FIG. 7 is an equivalent diagram of a four-path composite switch according to an embodiment of the present application;

FIG. 8(a) is a first schematic diagram illustrating a circuit of a 2CA implemented by a composite switch according to an embodiment of the present application;

FIG. 8(b) is a second schematic diagram illustrating the circuit of 2CA implemented by the composite switch according to an embodiment of the present application;

FIG. 8(c) is a third schematic diagram illustrating the circuit of 2CA implemented by the composite switch according to an embodiment of the present application;

FIG. 9 is a diagram illustrating signal flow of B1+B3 2CA according to an embodiment of the present application;

FIG. 10 is a first schematic diagram illustrating a circuit of 3CA implemented by a composite switch according to an embodiment of the present application;

FIG. 11 is a diagram illustrating signal flow of 3CA according to an embodiment of the present application;

FIG. 12 is a second schematic diagram illustrating the circuit of 3CA implemented by the composite switch according to an embodiment of the present application;

FIG. 13 is a schematic diagram illustrating a circuit of 4CA implemented by a composite switch according to an embodiment of the present application;

FIG. 14 is a schematic diagram illustrating the structural composition of a carrier aggregation device according to an embodiment of the present application;

FIG. 15 is a schematic diagram illustrating the structural composition of a communication apparatus according to an embodiment of the present application; and

FIG. 16 is a schematic flowchart illustrating a carrier aggregation method according to an embodiment of the present application.

### DETAILED DESCRIPTION

The technical solutions in the embodiments of the present application will be described below in conjunction with drawings in the embodiments of the present application. Obviously, the described embodiments are part of the embodiments of the present application, rather than all of the embodiments. Based on the embodiments in this application, all other embodiments obtained by those skilled in the art without creative work fall within the protection scope of the present application. The attached drawings are for reference and explanation only, and not used to limit the present application.

In order to facilitate the understanding of the technical solutions of the embodiments of the present application, the following describes related technologies involved in the embodiments of the present application.

Carrier aggregation (CA) may be divided into 2CA, 3CA, 4CA, etc. according to the number of carriers; and it may also be divided into uplink CA (ULCA) and downlink CA (DLCA) according to the signal flow direction. CA may also be divided into in-band CA and inter-band CA. The technical solutions in the embodiments of the present application mainly relate to the inter-band CA. From the aspect of hardware, the requirements of CA for the existing radio frequency components are not substantially increased, and only some changes has to be made to the original radio frequency circuits. In addition to the requirements of ULCA on radio frequency amplifiers (PA, Power Amplifier) for higher broadband characteristics and better linearity, DLCA does not have any additional requirements for the conducting component of a receiver, which facilitates the realization of various CA combinations. The CA function can increase the terminal throughput rate multiply without increasing the hardware cost greatly.

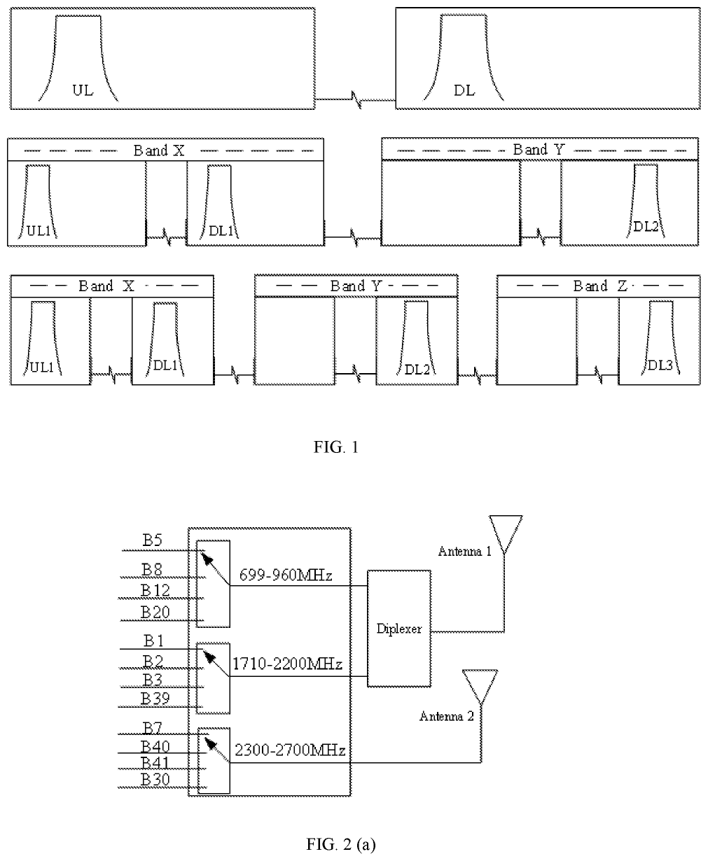

Generally, mobile phone terminals support many bands, and time-sharing and independent operations of different bands are realized through a single-pole multi-throw switch to ensure that at least one band is currently in conduction. According to the 3GPP protocol definition, CA needs to ensure that two (or more) different carrier frequencies are in operation concurrently. As shown in FIG. 1, the upper part, middle part and lower part illustrate examples of the operations of single carrier, 2DLCA and 3DLCA respectively, where, 2DLCA has one transmitting carrier and two receiving carriers, 3DLCA has one transmitting carrier and three receiving carriers, and the number of carriers in CA is increased in sequence. Similarly, in uplink CAs, the number of transmitting carriers is increased. For a CA combination with only one transmitting carrier, the band for transmitting signals is used as the primary carrier (PCC), and the band for only receiving signals is called the subcarrier (SCC). For example, in a 1+3+7 3DLCA, B1 is used as PCC, B3 is used as SCC1, and B7 is used as SCC2.

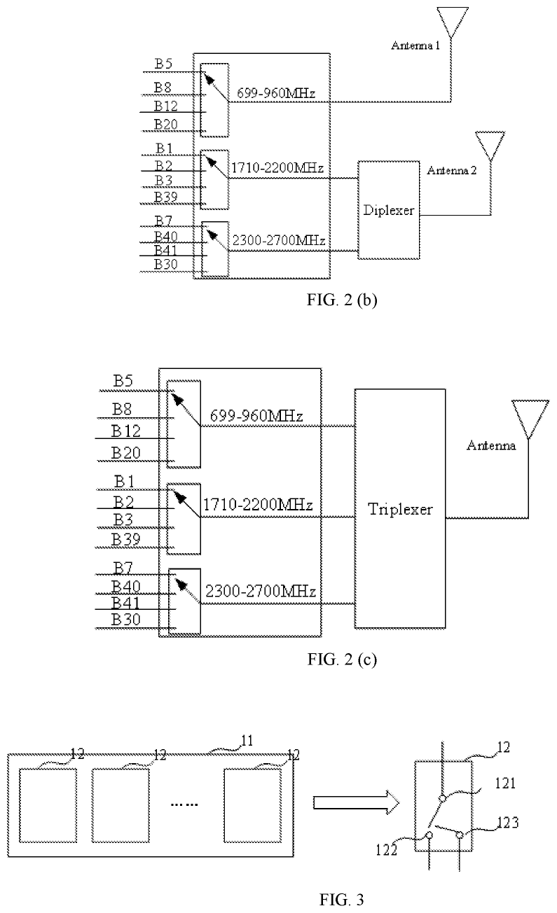

To support CA combinations of different bands, different bands need to be combined into one by a combiner to share the same antenna, or different bands are grouped and allocated to a plurality of antennas, each group is allocated to a single antenna. The current practice is to divide all bands into three groups: low frequency (LB), intermediate frequency (MB) and high frequency (HB), and realize the common types of 2CA and 3CA, such as MB+LB, MB+HB, HB+LB, HB+MB+LB according to different combinations. The 2CA combines two different carriers (carrier1 and carrier2) into one through a diplexer in circuit form, and the latter combines three different carriers (carrier1, carrier2 and carrier3) into one through a triplexer, as shown in FIG. 2(a), FIG. 2(b) and FIG. 2(c).

FIG. 2(a)-FIG. 2(c) selectively illustrates the typical topological form of a common CA circuit, which can realize common 2CA and 3CA combinations. It can be seen that for CA, a combiner must be added to the circuit to combine two (or more) carriers into one. The combiner will increase the insertion loss of the radio frequency path and cause diverge of the impedance matching, especially when obtaining HB+MB+LB 3CA, a triplexer of a type that can meet the index requirements cannot even be found. Sometimes, only a few of CA combinations need to be supported. For example, the operator only requires B1+B3, B1+B3+B7. At this time, a quadruplexer or hexaplexer may also be used, and only bands for CA are combined, and bands not for CA are omitted, so that the link insertion loss of the non-CA bands will not be affected, which is equivalent to tailoring the above-mentioned typical circuit. This tailored circuit can support only a few CA combinations, and the types of hexaplexer that can be used for 3CA are very limited.

In summary, in order to implement more CA combinations and to meet the requirements for radio frequency index of various combined CAs, the technical solutions of the embodiments of the present application propose a new CA implementation method, which improves the existing radio frequency front-end circuit, such that the CA combinations become more flexible and diverse, and link insertion loss is reduced as compared to traditional methods.

FIG. 3 is a schematic diagram illustrating the structural composition of the switch control circuit according to an embodiment of the present application. As shown in FIG. 3, the switch control circuit 11 comprises at least one composite switch 11, where the composite switch 11 comprises a plurality of switch units 12. Each of the plurality of switch units 12 has a first terminal 121, a second terminal 122 and a third terminal 123, the first terminal 121 is provided with a throw knife that is capable of being connected to the second terminal 122, and the third terminal 123 is provided with a throw knife that is capable of being connected to the second terminal 122.

In the embodiment of the present application, with respect to each of the plurality of switch units, the first terminal 121 of the switch unit is connected to a first antenna, the second terminal 122 of the switch unit is connected to a band (e.g., a radio frequency path for the band), and the third terminal 123 of the switch unit is connected to the second antenna.

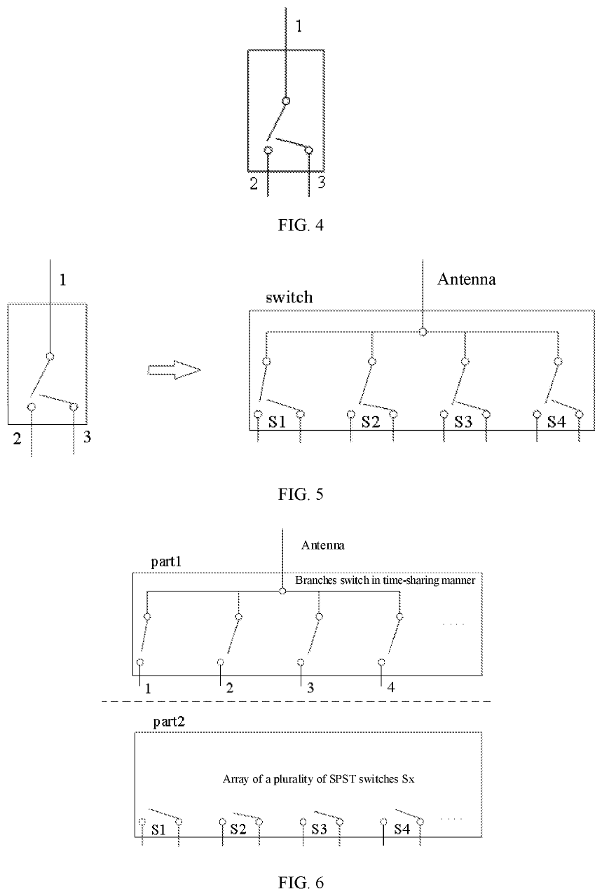

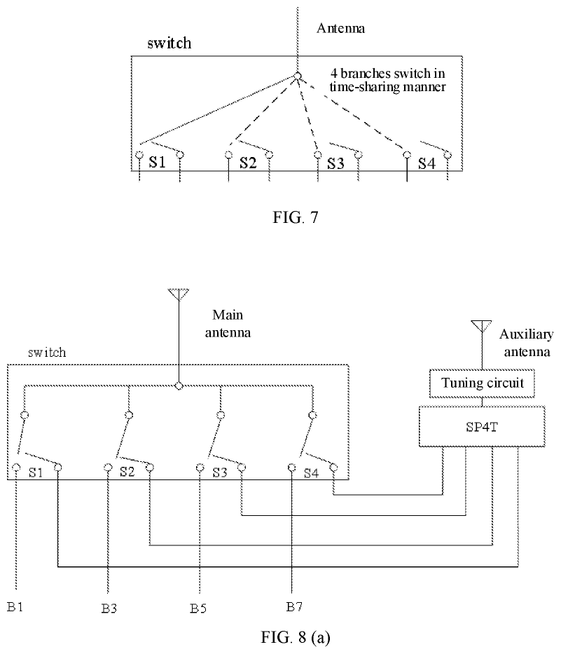

This application provides a basic switch unit 12. As shown in FIG. 4, 1 indicates the first terminal 121 of the switch unit 12, 2 indicates the second terminal 122 of the switch unit 12, and 3 indicates the third terminal 123 of the switch unit 12. The switch unit 12 can implement connection of 1 to 2, or connection of 2 to 3. FIG. 5 illustrates a multi-path composite switch 11 composed of basic switch units 12. FIG. 6 is an exploded schematic diagram illustrating the multi-path composite switch 11 in FIG. 5, in which the multi-path composite switch 11 may be divided into two parts: Part 1 (the common single-pole multi-throw switch part at the top of FIG. 6) and Part 2 (a array part of a plurality of single-pole single-throw switches at the bottom of FIG. 6). Part 1 is controlled by a set of GPIO (General Purpose Input Output) signals or MIPI (Mobile Industry Processor Interface) signals (that is, the first set of control signals), and Part 2 is controlled by another set of GPIO or MIPI signals (that is, the second set of control signals). As shown in FIG. 6, the ports 1, 2, 3, 4 in Part 1 correspond to S 1, S2, S3, S4 . . . in Part 2, respectively. When the switch of Part 1 is connected to any one of the ports 1, 2, 3, 4, the switch Sx in Part 2 corresponding to the port is disconnected, and other switches Sx are selected to be disconnected or in connection according to the CA situation. For example, when the switch of Part 1 is connected to port 1, S1 in part2 is disconnected, and S2, S3 and S4 are selected to be disconnected or in connection according to the CA situation (if a switch of S2, S3 and S4 is in connection, it are connected to the auxiliary antenna). The logic control of Part 1 and Part 2 may be combined together to implement a composite switch routing selection and CA function. FIG. 7 is an equivalent diagram of the multi-path composite switch 11 in FIG. 5.

In the embodiment of the present application, with respect to each of the plurality of switch units 12, the composite switch 11 is configured to control the connection of the first terminal 121 to the second terminal 122 of the switch unit 12 through a first set of control signals, and control the connection of the third terminal 123 to the second terminal 122 of the switch unit 12 through the second set of control signals; wherein, if the first terminal 121 of at least one first switch unit 12 of the plurality of switch units 12 is controlled to be connected to the second terminal 122 thereof through the first set of control signals, at least one first band connected to the second terminal 122 of the at least one first switch unit 12 is connected to the first antenna, so that the first antenna operates at the at least one first band; if the third terminal 123 of at least one second switch unit 12 of the plurality of switch units 12 is controlled to be connected to the second terminal 122 thereof through the second set of control signals, at least one second band connected to the second terminal 122 of the at least one second switch unit 12 is connected to the second antenna, so that the second antenna operates at the at least one second band. For example, an antenna operates at a band when the band is in conduction with the antenna. Further, the composite switch 11 is configured to control the third terminal 123 of the at least one first switch unit 12 to be disconnected from the second terminal 122 thereof through the second set of control signals, if the first terminal 121 of the at least one first switch unit 12 of the plurality of switch units 12 is controlled to be connected to the second terminal 122 thereof through the first set of control signals; or, if the third terminal 123 of the at least one second switch unit 12 of the plurality of switch units 12 is controlled to be connected to the second terminal 122 thereof through the second set of control signals, control the first terminal 121 of the at least one second switch unit 12 to be disconnected from the second terminal 122 thereof through the first set of control signals. That is, one switch unit can only control the corresponding band to be connected to one antenna (the first antenna or the second antenna).

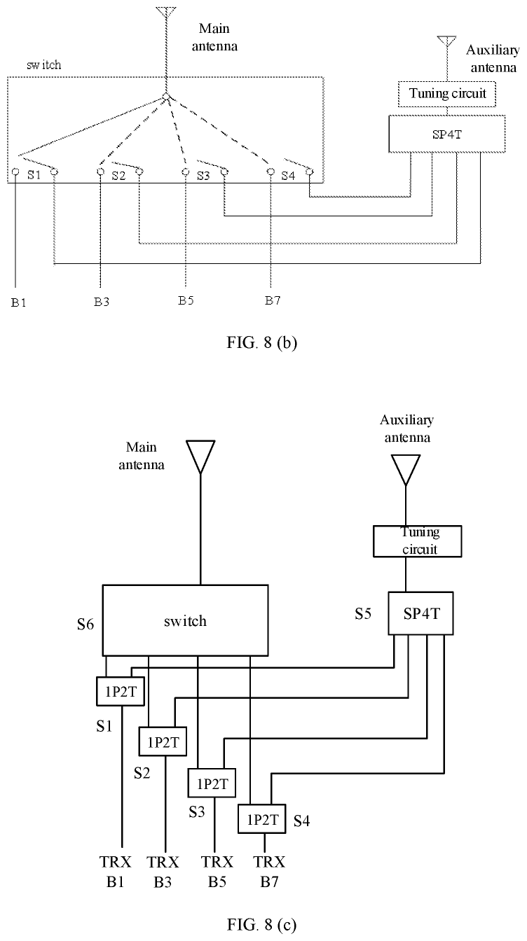

Referring to FIGS. 8(a)-8(c) and taking that the switch control circuit is applied to 2CA as an example, the main antenna in the drawings represents the first antenna, the auxiliary antenna represents the second antenna; or the main antenna represents the second antenna, the auxiliary antenna represents the first antenna; and the switch represents a composite switch. As shown in FIGS. 8(a)-8(c), the switch on the left controls the connection and disconnection of the ports of respective switch units through GPIO or MIPI, on one hand, each of the bands is connected to the main antenna through switches S1, S2, S3 or S4 respectively, on the other hand, each band is connected to the SP4T switch on the right through switches S1, S2, S3 or S4, and then the SP4T switch is connected to the auxiliary antenna through a tuning circuit. This circuit structure can support CA with any combination of two bands among B1, B3, B5 and B7. For example, when B1+B3 CA is in operation, the S1 switch gates the auxiliary antenna, and the S3 switch gates the main antenna, or vice versa. It should be noted that the logics of Sx switches corresponding to the two carriers are always opposite to each other.

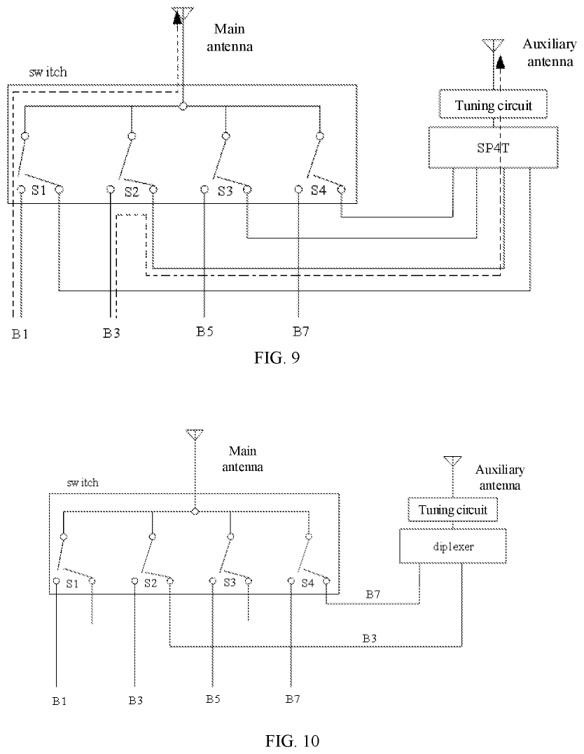

The signal direction of two carriers are shown in FIG. 9, the one on the left is the signal direction of B1 carrier, and the one on the right represents the signal direction of B3 carrier. When B1 and B3 do not make CA, they are conducted in a time-sharing manner through the switch. The same applies to other 2CA combinations. It can be seen that when the 2CA combination in this application is in operation, the link insertion loss is smaller than that of the traditional 2CA circuit. The circuits in FIGS. 8(a)-8(c) can implement CA with any combination of two bands among the four bands. In this application, a tuning circuit and a SP4T switch are added to the auxiliary antenna side. Only one carrier operates on the auxiliary antenna at one time, and the tuning switch only needs to tune the carrier alone, such that the difficulty of antenna tuning is reduced. Generally, there is a tuning circuit at the main antenna side, and in this application, only one carrier operates on the main antenna at one time in the 2CA circuit, such that the difficulty of antenna tuning is also reduced. Therefore, the difficulty of antenna tuning may be reduced by separately tuning the two antennas.

In the embodiment of the present application, the switch control circuit further comprises a single-pole multi-throw switch, wherein, if the third terminal 123 of one second switch unit of the plurality of switch units 12 is controlled to be connected to the second terminal 122 thereof through the second set of control signals, one second band corresponding to the one second switch unit is gated through the single-pole multi-throw switch on the second antenna side and then is connected to the second antenna, referring to the SP4T switch in FIG. 9.

In the embodiment of the present application, the switch control circuit further comprises a first combiner, wherein, if the first terminals 121 of at least two first switch units of the plurality of switch units 12 are connected to the second terminals 122 thereof respectively through the first set of control signals, at least two first bands corresponding to the at least two first switch units are combined by a first combiner at the first antenna side and then connected to the first antenna. Similarly, the switch control circuit further comprises a second combiner, wherein, if the third terminals 123 of at least two second switch units 12 of the plurality of switch units 12 are controlled to be connected to the second terminals 122 of the at least two second switch units 12 respectively through the second set of control signals, at least two second bands corresponding to the at least two second switch units 12 are combined by a second combiner at the second antenna side and then connected to the second antenna.

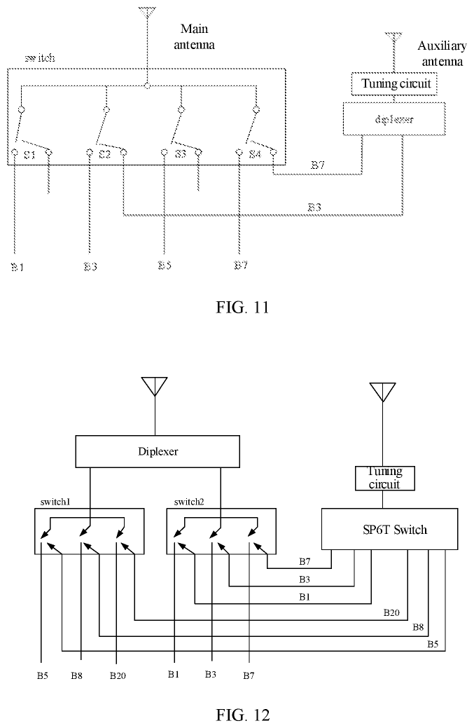

Referring to FIG. 10 and taking that the switch control circuit is applied to 3CA as an example, FIG. 10 is obtained based on the 2CA shown in FIG. 8, where the SP4T switch of the auxiliary antenna is replaced with a diplexer which is used as a combiner. In addition to 2CA, 3+5+73 CA or 1+3+73 CA may be implemented. It can be seen that the insertion loss of this 3CA circuit structure is smaller than that of the traditional 3CA circuit. The signal flow diagram of 3CA is shown in FIG. 11.

Regarding the insertion loss, the insertion loss of 2CA in this application is compared with that of the traditional solution, as shown in table 1. From Table 1, it can be seen that the CA circuit in this application reduces the insertion loss of carrier 1 by 0.5 dB, and the insertion loss of carrier 2 is almost the same. The 3CA insertion loss in this application is compared with that of the traditional 3CA solution, as shown in Table 3. It can be seen that the insertion losses of the three carriers in the CA circuit of this application are significantly reduced.

TABLE 1

| | conducting component | 698-960 MHz | 1710-2170 MHz | 2300-2700 MHz |
|---|---|---|---|---|
| 2CA | | | | |
| carrier 1/ | diplexer | 0.59 | 0.54 | 0.54 |
| carrier 2 | SPMT | 0.5 | 0.65 | 0.7 |
| | total loss | 1.09 | 1.19 | 1.24 |
| transitional solution | | | | |
| carrier 1/ | SPMT | 0.5 | 0.65 | 0.7 |
| carrier 2 | SP2T | 0.3 | 0.4 | 0.5 |
| | total loss | 0.8 | 1.05 | 1.2 |
| 2CA solution in this | | | | |
| invention | | | | |
| carrier 1 | SPMT | 0.5 | 0.65 | 0.7 |
| carrier 2 | SPMT | 0.5 | 0.65 | 0.7 |
| | SP2T | 0.3 | 0.4 | 0.5 |
| | total loss | 0.8 | 1.05 | 1.2 |

TABLE 2

| | conducting | 698-960 | 1710-2170 | 2300-2700 |
|---|---|---|---|---|
| 3CA | component | MHz | MHz | MHz |
| carrier 1/ | triplexer | 0.45-0.63 | 0.8-1.23 | 1.12-1.47 |
| carrier 2/ | SPMT | 0.5 | 0.65 | 0.7 |
| carrier 3 | total loss | 1.13 | 1.88 | 1.82 |
| 3CA solution | | | | |
| in this | conducting | 698-960 | 1710-2170 | 2300-2700 |
| invention | component | MHz | MHz | MHz |
| carrier 1 | SPMT | 0.5 | 0.65 | 0.7 |
| carrier 2 | diplexer | 0.59 | 0.54 | 0.54 |
| | SP2T | 0.3 | 0.4 | 0.5 |
| | total loss | 0.89 | 0.94 | 1.04 |
| carrier 3 | diplexer | 0.59 | 0.54 | 0.54 |
| | SP2T | 0.3 | 0.4 | 0.5 |
| | total loss | 0.89 | 0.94 | 1.04 |

In the embodiment of the present application, the switch control circuit further comprises a first combiner and/or a second combiner, wherein, if the switch control circuit comprises at least two composite switches 11, at least two sets of first bands corresponding to the at least two composite switches 11 are respectively combined by the first combiner at the first antenna side and then connected to the first antenna; and/or, the at least two sets of second bands corresponding to the at least two composite switches 11 are respectively combined by the second combiner at the second antenna side and then connected to the second antenna.

Referring to FIG. 12 and taking that the switch control circuit is applied to 3CA as an example, the main antenna is divided by a diplexer into two paths: a path for high frequency and a path for low frequency, and the two paths are connected to switch 1 and switch 2 respectively, which can implements more combinations of 2CA and 3CA.

In the embodiment of the present application, the switch control circuit further comprises at least two single-pole multi-throw switches and a second combiner, wherein, if the third terminals 123 of at least two second switch units 12 of the plurality of switch units 12 are controlled to be connected to the second terminal 122 thereof respectively through the second set of control signals, at least two second bands corresponding to the at least two second switch units are gated by the at least two single-pole multi-throw switches at a second antenna side, respectively, and combined by the second combiner and then connected to the second antenna.

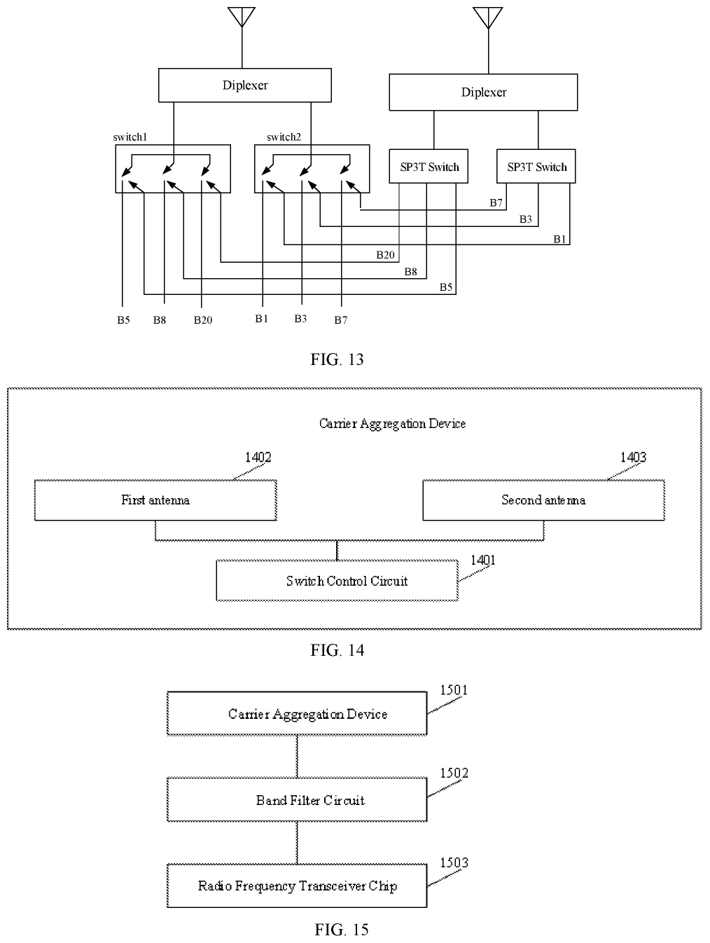

Referring to FIG. 13 and taking that the switch control circuit is applied to 4CA as an example, FIG. 13 is obtained based on FIG. 12 and the SP6T switch of the auxiliary antenna is replaced with two SP3T switches, and each SP3T switch implements the gating of one band.

In the embodiment of the present application, the composite switch 11 is further configured to control the first terminal 121 of at least one third switch unit 12 of the plurality of switch units 12 to be disconnected from the second terminal thereof through the first set of control signals, and control the third terminal 123 of the at least one third switch unit 12 to be disconnected from the second terminal 122 thereof through the second set of control signals. Here, some of the switch units in the composite switch may neither be connected to the first antenna nor be connected to the second antenna, and the bands corresponding to these switch units are not used for communication.

FIG. 14 is a schematic diagram illustrating the structural composition of the carrier aggregation device according to an embodiment of the present application. As shown in FIG. 14, the device comprises: a switch control circuit 1401, a first antenna 1402 and a second antenna 1403, wherein, the switch control circuit 1401 is configured to control at least one first band to be connected to the first antenna 1402, and at least one second band to be connected to the second antenna 1403; the first antenna 1402 is configured to transmit respective carrier signals in the at least one first band; the second antenna 1403 is configured to transmit respective carrier signals in the at least one second band.

Those skilled in the art should understand that the function implemented by respective switch units in the switch control circuit shown in FIG. 14 may be understood with reference to the relevant description of the aforementioned switch control circuit.

In the technical solution of the embodiment of the present application, a switch control circuit is provided. The switch control circuit comprises at least one composite switch, where, the composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal. The switch control circuit controls at least one first band to be connected to the first antenna, and at least one second band to be connected to the second antenna, such that respective carrier signals are transmitted over the at least one first band through the first antenna, and respective carrier signals are transmitted over the at least one second band through the second antenna. In the embodiment of the present application, the switch control circuit and the two antennas cooperate to implement the CA combination of different bands, such that the CA combinations become more flexible and diverse, and link insertion loss is reduced compared to traditional methods. In addition, the number of combiners could be reduced and the component costs can be saved.

The embodiments of the application are different from the traditional CA design, and the combiners will be used as few as possible. When implementing the CA combination in the same situation, the technical solution of the embodiment of the present application will adopts one less combiner than the traditional method. At the same time, this application needs to add one antenna (called an auxiliary antenna) to the mobile phone terminal. Finally, the embodiments of the present application can solve the existing problem that the index requirement cannot be satisfied when the HB+MB+LB3 CA is used and when the number of the combinations is relatively big.

The technical solutions of the embodiments of the present application implement the CA function through a dual-antenna manner, and can select two or three bands from a plurality of 5G bands to form 2CA or 3CA. Compared with the traditional CA circuit, the circuit form in this application supports more CA combinations and has smaller link insertion loss.

FIG. 15 is a schematic diagram illustrating the structural composition of the communication apparatus according to an embodiment of the present application. As shown in FIG. 15, the communication apparatus comprises a carrier aggregation device 1501, a band filter circuit 1502 and a radio frequency transceiver chip 1503, where, the radio frequency transceiver chip 1503 is configured to transmit carrier signals in at least one band to the band filter circuit 1502; the band filter circuit 1502 is configured to receive carrier signals in at least one band from the radio frequency transceiver chip 1503, filter the carrier signals in at least one band, and send them to the carrier aggregation device 1501; or, receive carrier signals in at least one band from the carrier aggregation device 1501, filter the carrier signals in at least one band, and send them to the radio frequency transceiver chip 1503; the carrier aggregation device 1501 is configured to transmit carrier signals in at least one band to the band filter circuit 1502.

The carrier aggregation device of the embodiment of the present application comprises a switch control circuit, a first antenna and a second antenna. Two bands may be arbitrarily selected from a plurality of 5G bands to simultaneously transmit or receive carrier signals through two antennas. The switch control circuit of the embodiment of the present application may be understood with reference to the relevant description of the aforementioned carrier aggregation device.

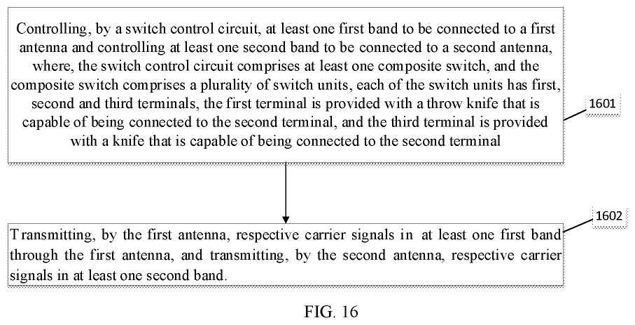

FIG. 16 is a schematic flowchart illustrating the carrier aggregation method according to an embodiment of the present application. As shown in FIG. 16, the carrier aggregation method comprises the following steps: Step 1601, controlling, by a switch control circuit, at least one first band to be connected to a first antenna and controlling, by the switch control circuit, at least one second band to be connected to a second antenna, wherein, the switch control circuit comprises at least one composite switch, and the composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal.

In the embodiment of the present application, with respect to each of the plurality of switch units, the connection of the first terminal to the second terminal of the switch unit is controlled through a first set of control signals, and the connection of the third terminal to the second terminal of the switch unit is controlled through the second set of control signals; wherein, if the first terminal of at least one first switch unit of the plurality of switch units is controlled to be connected to the second terminal thereof through the first set of control signals, at least one first band connected to the second terminal of the at least one first switch unit is connected to the first antenna; if the third terminal of at least one second switch unit of the plurality of switch units is controlled to be connected to the second terminal thereof through the second set of control signals, at least one second band connected to the second terminal of the at least one second switch unit is connected to the second antenna. Further, if the first terminal of the at least one first switch unit of the plurality of switch units is controlled to be connected to the second terminal thereof through the first set of control signals, the third terminal of the at least one first switch unit are controlled to be disconnected from the the second terminal thereof through the second set of control signals; or, if the third terminal of the at least one second switch unit of the plurality of switch units is controlled to be connected to the second terminal thereof through the second set of control signals, the first terminal of the at least one second switch unit are controlled to be disconnected from the second terminal thereof through the first set of control signals. That is, one switch unit can only control the corresponding band to be connected to one antenna (the first antenna or the second antenna).

Referring to FIGS. 8(a)-8(c) and taking that the switch control circuit is applied to 2CA as an example, the main antenna in the drawings represents the first antenna, the auxiliary antenna represents the second antenna; or the main antenna represents the second antenna, the auxiliary antenna represents the first antenna; and the switch represents a composite switch. As shown in FIGS. 8(a)-8(c), the switch on the left controls the connection and disconnection of the ports of respective switch units through GPIO or MIPI, on one hand, each of the bands is connected to the main antenna through switches S1, S2, S3 or S4 respectively, on the other hand, each band is connected to the SP4T switch on the right through switches S1, S2, S3 or S4, and then the SP4T switch is connected to the auxiliary antenna through a tuning circuit. This circuit structure can support CA with any combination of two bands among B1, B3, B5 and B7. For example, when B1+B3 CA is in operation, the S1 switch gates the auxiliary antenna, and the S3 switch gates the main antenna, or vice versa. It should be noted that the logics of Sx switches corresponding to the two carriers are always opposite to each other.

The signal direction of two carriers are shown in FIG. 9, the one on the left is the signal direction of B1 carrier, and the one on the right represents the signal direction of B3 carrier. When B1 and B3 do not make CA, they are conducted in a time-sharing manner through the switch. The same applies to other 2CA combinations. It can be seen that when the 2CA combination in this application is in operation, the link insertion loss is smaller than that of the traditional 2CA circuit. The circuits in FIGS. 8(a)-8(c) can implement CA with any combination of two bands among the four bands. In this application, a tuning circuit and a SP4T switch are added to the auxiliary antenna side. Only one carrier operates on the auxiliary antenna at one time, and the tuning switch only needs to tune the carrier alone, such that the difficulty of antenna tuning is reduced. Generally, there is a tuning circuit at the main antenna side, and in this application, only one carrier operates on the main antenna at one time in the 2CA circuit, such that the difficulty of antenna tuning is also reduced. Therefore, the difficulty of antenna tuning may be reduced by separately tuning the two antennas.

In the embodiment of the present application, if the third terminal of one second switch unit of the plurality of switch units is controlled to be connected to the second terminal thereof through the second set of control signals, one second band corresponding to the one second switch unit is gated through the single-pole multi-throw switch on the second antenna side and then is connected to the second antenna, referring to the SP4T switch in FIG. 9.

In the embodiment of the present application, if the first terminals of at least two second switch units of the plurality of switch units are controlled to be connected to the second terminals thereof respectively through the second set of control signals, at least two second bands corresponding to the at least two second switch units are combined by a second combiner at the second antenna side and then connected to the second antenna. Similarly, if the first terminals of at least two first switch units of the plurality of switch units are connected to the second terminals thereof respectively through the first set of control signals, at least two first bands corresponding to the at least two first switch units are combined by a first combiner at the first antenna side and then connected to the first antenna.

Referring to FIG. 10 and taking that the switch control circuit is applied to 3CA as an example, FIG. 10 is obtained based on the 2CA shown in FIG. 8, where the SP4T switch of the auxiliary antenna is replaced with a diplexer which is used as a combiner. In addition to 2CA, 3+5+73 CA or 1+3+73 CA may be implemented. It can be seen that the insertion loss of this 3CA circuit structure is smaller than that of the traditional 3CA circuit. The signal flow diagram of 3CA is shown in FIG. 11.

In the embodiment of the present application, if the switch control circuit comprises at least two composite switches 11, at least two sets of first bands corresponding to the at least two composite switches 11 are respectively combined by the first combiner at the first antenna side and then connected to the first antenna; and/or, the at least two sets of second bands corresponding to the at least two composite switches 11 are respectively combined by the second combiner at the second antenna side and then connected to the second antenna.

Referring to FIG. 12 and taking that the switch control circuit is applied to 3CA as an example, the main antenna is divided by a diplexer into two paths: a path for high frequency and a path for low frequency, and the two paths are connected to switch 1 and switch 2 respectively, which can implements more combinations of 2CA and 3CA.

In the embodiment of the present application, if the third terminals of at least two second switch units of the plurality of switch units are controlled to be connected to and the second terminal thereof respectively through the second set of control signals, at least two second bands corresponding to the at least two second switch units are gated by the at least two single-pole multi-throw switches at a second antenna side, respectively, and combined by the second combiner and then are connected to the second antenna.

Referring to FIG. 13 and taking that the switch control circuit is applied to 4CA as an example, FIG. 13 is obtained based on FIG. 12 and the SP6T switch of the auxiliary antenna is replaced with two SP3T switches, and each SP3T switch implements the gating of one band.

In the embodiment of the present application, the first terminal of at least one third switch unit of the plurality of switch units is controlled to be disconnected from the second terminal thereof through the first set of control signals, and the third terminal of the at least one third switch unit is controlled to be disconnected from the second terminal thereof through the second set of control signals. Here, some of the switch units in the composite switch may neither be connected to the first antenna nor be connected to the second antenna, and the bands corresponding to these switch units are not used for communication.

Step 1602: transmitting respective carrier signals in the at least one first band through the first antenna, and transmitting respective carrier signals in the at least one second band through the second antenna.

The technical solution of the embodiment of the present application provides a circuit form in which the CA function is implemented through a dual-antenna manner and the main carrier and the subcarrier can exchange antenna positions. Compared with the traditional solutions, the solution has more flexible and changeable CA combinations and can implement any combination of CA functions, and the insertion loss does not increase significantly compared to the non-CA situation. The flexibility of adjusting the transmission impedance of different two paths of carriers is increased under CA conditions. This circuit form is more suitable for the concurrent operation of multiple carriers in 5G communication, as 5G has high frequencies and wide bands, the requirements for RF front-end combiners are higher, if it is required to achieve the carrier aggregation function for the bands of sub 6G or even 5G millimeter, adding a combiner on the link will bring greater challenges to impedance tuning. The antenna size under 5G technology tends to be miniaturized, the multi-antenna technology will become more common, and the directionality of antenna will be relatively strong, so the method of 5G band carrier aggregation through a dual-antenna manner will become more advantageous.

The technical solutions described in the embodiments of the present application may be combined arbitrarily without conflict.

In the several embodiments according to the present application, it should be understood that the disclosed method and intelligent apparatus may be implemented in other ways. The apparatus embodiments described above are merely illustrative. For example, the division of the units is only a logical function division, and there may be other divisions in actual implementation. For example, a plurality of units or components may be combined, or integrated into another system, or some features may be ignored or not implemented. In addition, the coupling, or direct coupling, or communication connection between the components shown or discussed may be indirect coupling or communication connection through some interfaces, apparatus or units, and may be electrical, mechanical or in other forms.

The units described above as separate components may or may not be physically separated, and the components displayed as units may or may not be physical units, that is, they may locate in one place or distributed to a plurality of network unit; some or all of the units may be selected according to actual needs to achieve the purpose of the solution of this embodiment.

In addition, the functional units in the embodiments of the present application may be all integrated into a second processing unit, or respective unit may be individually used as one unit, or two or more units may be integrated into one unit; the above-mentioned integrated unit may be implemented either in the form of hardware or in the form of hardware plus software functional unit.

The above are only specific implementations of the present application, but the protection scope of the present application is not limited thereto. Any person skilled in the art can easily conceive changes or replacements within the technical scope disclosed in this application and these changes or replacements shall all fall within the scope of protection of this application.

What is claimed is:

1. A switch control circuit, comprising:
at least one composite switch, wherein,
each of the at least one composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal.

2. The switch control circuit according to claim 1, wherein the first terminal of each respective switch unit of the plurality of switch units is connected to a first antenna, the second terminal of the respective switch unit is connected to a radio frequency path for a respective band, and the third terminal of the respective switch unit is connected to a second antenna.

3. The switch control circuit according to claim 2, wherein the composite switch is configured to control connection of the first terminal to the second terminal of each of the plurality of switch units through a first set of control signals, and control connection of the third terminal to the second terminal of each of the plurality of switch units through a second set of control signals;
wherein, if the first terminal of at least one first switch unit of the plurality of switch units is controlled to be connected to the second terminal thereof through the first set of control signals, the first antenna operates at at least one first band connected to the second terminal of the at least one first switch unit;
if the third terminal of at least one second switch unit of the plurality of switch units is controlled to be connected to the second terminal thereof through the second set of control signals, the second antenna operates at at least one second band connected to the second terminal of the at least one second switch unit.

4. The switch control circuit according to claim 3, wherein the composite switch is configured to control the third terminal of the at least one first switch unit of the plurality of switch units to be disconnected from the second terminal thereof through the second set of control signals, if the first terminal of the at least one first switch unit of the plurality of switch units is controlled to be connected to the second terminal thereof through the first set of control signals; or, control the first terminal of the at least one second switch unit of the plurality of switch units to be disconnected from the second terminal thereof through the first set of control signals, if the third terminal of the at least one second switch unit is controlled to be connected to the second terminal thereof through the second set of control signals.

5. The switch control circuit according to claim 3, wherein the switch control circuit further comprises a first combiner; wherein,
if the first terminals of at least two first switch units of the plurality of switch units are controlled to be connected to the second terminals thereof respectively through the first set of control signals, at least two first bands corresponding to the at least two first switch units are combined by the first combiner at a first antenna side and then the first antenna operates at the combined first band.

6. The switch control circuit according to claim 3, wherein the switch control circuit further comprises a first combiner and/or a second combiner; wherein,
if the switch control circuit comprises at least two composite switches, at least two sets of first bands corresponding to the at least two composite switches are respectively combined by the first combiner at a first antenna side and then the first antenna operates at the combined first bands; and/or, the at least two sets of second bands corresponding to the at least two composite switches are respectively combined by the second combiner at a second antenna side and then the second antenna operates at the combined second bands.

7. The switch control circuit of claim 3, wherein the switch control circuit further comprises a single-pole multi-throw switch; wherein,
if the third terminal of one second switch unit of the plurality of switch units is controlled to be connected to the second terminal thereof through the second set of control signals, one second band corresponding to the one second switch unit is gated through the single-pole multi-throw switch at a second antenna side and then the second antenna operates at the gated second band.

8. The switch control circuit according to claim 3, wherein the switch control circuit further comprises a second combiner; wherein,
if the third terminals of at least two second switch units of the plurality of switch units are controlled to be connected to the second terminal thereof respectively through the second set of control signals, at least two second bands corresponding to the at least two second switch units are combined by the second combiner at a second antenna side and then the second antenna operates at the combined second band.

9. The switch control circuit of claim 3, wherein the switch control circuit further comprises at least two single-pole multi-throw switches and a second combiner; wherein,
if the third terminals of at least two second switch units of the plurality of switch units are controlled to be connected to the second terminal thereof respectively through the second set of control signals, at least two second bands corresponding to the at least two second switch units are gated by the at least two single-pole multi-throw switches at a second antenna side, respectively, and combined by the second combiner and then the second antenna operates at the combined second band.

10. The switch control circuit according to claim 3, wherein the composite switch is further configured to control the first terminal of at least one third switch unit of the plurality of switch units to be disconnected from the second terminal thereof through the first set of control signals, and control the third terminal of the at least one third switch unit to be disconnected from the second terminal thereof through the second set of control signals.

11. A carrier aggregation device, comprising the switch control circuit according to claim 1, a first antenna and a second antenna, wherein,
the switch control circuit is configured to control the first antenna to operate at at least one first band, and control the second antenna to operate at at least one second band;
the first antenna is configured to transmit respective carrier signals in the at least one first band;
the second antenna is configured to transmit respective carrier signals in the at least one second band.

12. A communication apparatus, comprising the carrier aggregation device according to claim 11, a band filter circuit and a radio frequency transceiver chip, wherein,
the radio frequency transceiver chip is configured to send to or receive from the band filter circuit, carrier signals in at least one band;
the band filter circuit is configured to receive carrier signals in at least one band from the radio frequency transceiver chip, filter the carrier signals in at least one band, and send them to the carrier aggregation device; or, receive carrier signals in at least one band from the carrier aggregation device, filter the carrier signals in at least one band, and send them to the radio frequency transceiver chip; and
the carrier aggregation device is configured to send to or receive from the band filter circuit, carrier signals in at least one band.

13. A carrier aggregation method, comprising:
controlling, by a switch control circuit, a first antenna to operate at at least one first band and controlling, by the switch control circuit, a second antenna to operate at at least one second band, wherein, the switch control circuit comprises at least one composite switch, and each of the at least one composite switch comprises a plurality of switch units, each of the plurality of switch units has a first terminal, a second terminal and a third terminal, the first terminal is provided with a throw knife that is capable of being connected to the second terminal, and the third terminal is provided with a throw knife that is capable of being connected to the second terminal; and
transmitting, by the first antenna, respective carrier signals over the at least one first band through the first antenna, and transmitting, by the second antenna, respective carrier signals in the at least one second band.

14. The method of claim 13, wherein the first terminal of each respective switch unit of the plurality of switch units is connected to a first antenna, the second terminal of the respective switch unit is connected to a radio frequency path for a respective band, and the third terminal of the respective switch unit is connected to a second antenna.

15. The method according to claim 14, wherein controlling, by the switch control circuit, the first antenna to operate at at least one first band, and controlling, by the switch control circuit, the second antenna to operate at least one second band comprises:
controlling connection of the first terminal to the second terminal of each of the plurality of switch units through a first set of control signals, and controlling connection of the third terminal to the second terminal of each of the plurality of switch units through a second set of control signals;
wherein, if the first terminal of at least one first switch unit of the plurality of switch units is controlled to be connected to the second terminal thereof through the first set of control signals, the first antenna operates at at least one first band connected to the second terminal of the at least one first switch unit;
if the third terminal of at least one second switch unit of the plurality of switch units is controlled to be connected to the second terminal thereof through the second set of control signals, the second antenna operates at at least one second band connected to the second terminal of the at least one second switch unit .

16. The method of claim 15, further comprising:
if the first terminal of the at least one first switch unit of the plurality of switch units is controlled to be connected to the second terminal thereof through the first set of control signals, controlling the third terminal of the at least one first switch unit of the plurality of switch units to be disconnected from the second terminal thereof through the second set of control signals; or,
if the third terminal of the at least one second switch unit of the plurality of switch units is controlled to be connected to the second terminal thereof through the second set of control signals, controlling the first terminal of the at least one second switch unit to be disconnected from the second terminal thereof through the first set of control signals.

17. The method of claim 15, wherein,
if the first terminals of at least two first switch units of the plurality of switch units are controlled to be connected to the second terminals thereof respectively through the first set of control signals, combining at least two first bands corresponding to the at least two first switch units by the first combiner at a first antenna side so that the first antenna operates at the combined first band.

18. The method of claim 15, wherein,
if the switch control circuit comprises at least two composite switches, combining at least two sets of first bands corresponding to the at least two composite switches respectively by a first combiner at a first antenna side so that the first antenna operates at the combined first bands; and/or, combining the at least two sets of second bands corresponding to the at least two composite switches respectively by a second combiner at a second antenna side so that the second antenna operates at the combined second bands.

19. The method of claim 15, wherein:
if the third terminal of one second switch unit of the plurality of switch units is controlled to be connected to the second terminal thereof through the second set of control signals, gating one second band corresponding to the one second switch unit through a single-pole multi-throw switch at a second antenna side so that the second antenna operates at the combined second band.

20. The method of claim 15, wherein:
if the third terminals of at least two second switch units of the plurality of switch units are controlled to be connected to the second terminal thereof respectively through the second set of control signals, combining at least two second bands corresponding to the at least two second switch units by a second combiner at a second antenna side so that the second antenna operates at the combined second band.
